(19) United States
(12) Patent Application Publication
(10) Pub. No.: US 2023/0002879 A1
(43) Pub. Date: Jan. 5, 2023

(54) GAS RING FOR A PVD SOURCE

(71) Applicant: EVATEC AG, Trübbach (CH)

(72) Inventors: Andreas Mark, Wangs (CH); Stefan Rhyner, Buchs (CH); Edmund Schüngel, Buchs (CH)

(21) Appl. No.: 17/757,234

(22) PCT Filed: Nov. 10, 2020
(86) PCT No.: PCT/EP2020/081650

§ 371 Date: Jun. 13, 2022

(30) Foreign Application Priority Data
Dec. 13, 2019 (CH) 01623/19

(51) Int. Cl. C23C 14/22; C23C 14/34

(52) U.S. Cl. CPC C23C 14/228; C23C 14/3407

(57) ABSTRACT

A gas ring for a PVD-source with a cathode having a target for material deposition. The gas ring includes an inner rim and an outer rim and at least one flange between the inner and the outer rim. The gas ring further includes: —a gas inlet; —gas openings arranged circumferentially in or near the inner rim; —at least one circumferential gas channel connected to the gas inlet and/or the gas openings; —a cooling duct.

The invention refers to a gas ring according to claim 1, to a PVD-source comprising such a gas ring according to claim 16 and to a vacuum chamber comprising such a gas ring according to claim 18.

### TECHNICAL BACKGROUND

Gas rings encompassing a PVD-source (where PVD stands for physical vapor deposition) near a front surface of a planar target mounted to that source are frequently used in a wide-spread field of surface engineering applications. Thereby an even gas distribution over the whole active surface area, which is the area to be sputtered or evaporated and/or to a substrate in front of and centered to the target should be achieved. Such gas rings are often combined with other measurements like a rotating magnetic field or a rotating target as an example for circular or hexagonal PVD-sources, or with other types of variable magnetic fields, as an example for rectangular elongated targets, to optimize target use and to avoid redeposition or formation of passivated areas on the front surface. Such redeposits and passivated areas can be detrimental due to dust formation or arcing for any type of surface engineering. Due to still growing process requirements within the semiconductor and the optic industries, however, it was found that also the process, e.g. the sputter gas distribution of state-of-the-art gas rings should be improved for certain highly sophisticated processes in the as mentioned industries. A further point is the widespread use of Radio Frequency (RF)-sputtering processes to sputter inter alia also isolating or semiconducting materials. Such processes often generate a high inductive heat load also to components which are not electrically connected to the RF-supply especially when they are near or even encompassing the sputter-source like gas rings do. Such problems may be intensified due to parasitic plasmas which can be formed due to, e.g. heat deformation and/or RF induced effects including the formation of different surface potentials between the gas ring and nearby components of the vacuum chamber or the PVD-source, shift of a dark-room distance between gas ring and components on cathodic potential and the like.

Despite of the focus on sputter processes and respective sputter sources in the following, it should be mentioned that an improvement of state-of-the-art gas rings would be beneficial also for other PVD-sources like cathodic arc sources if high standards in gas distribution and process reliability should be met.

### Definitions

Within the following the meaning of ring, circumferential, and other terms originally used for circular geometries also encloses other, e.g. oval, multi-angular, like rectangular or hexangular geometries, thereby encompassing also respective gas rings for oval or angular cathode geometries of planar cathodes, e.g. for use in or with any planar sputter sources, which can be magnetrons, or with other planar PVD-sources, which can be cathodic arc evaporators.

The use of the terms “inward” and “outward” refer to directions towards and away from the center point/axis or center line/plane of a respective target/source geometry. The use of the terms up, upwards and down, downwards or lower refer to the drawings as shown in the figures and not to a possible direction of the gas ring or PVD-source when mounted as PVD-sources can be mounted in various positions of a vacuum chamber, e.g. on top or bottom or a sidewall. The standard anode as referred to in the following is a grounded anode as described in detail below. However, inventive vacuum chambers may comprise also other types of anodes mounted on another place of the vacuum chamber and e.g. providing a higher potential difference than between the grounded anode and the cathode. Such vacuum chambers are explicitly enclosed within the scope of the present invention, as long as the features of the gas ring and the PVD-source comply with the inventive design as disclosed below.

### SUMMARY OF THE INVENTION

The aim of the present invention is to provide a gas ring which avoids the drawbacks of the state-of-the-art as mentioned above and to improve gas distribution as well as process reliability. Further sub-targets are temperature stabilization and minimization of thermal extension during PVD-processes, optimized electrical lay-out also for RF-applications, ease of handling.

The gas ring is designed for a PVD-source which comprises a cathode, e.g. a cathode for sputtering or a cathode for cathodic arc processes, by which depending on the process parameters deposition of target material on a substrate surface or etching of a substrate surface can be performed. Said gas ring has an inner rim to encompass at least in part the anode and/or an outer margin of the cathode which consists of a cathode base with a power connector and a target made from material to be sputtered or evaporated. The gas ring further has an outer rim and at least one flange between the inner and the outer rim by which it can be mounted into a respective opening of a vacuum chamber, to a cathode base supporting the cathode and/or to an anode. Said gas ring further comprises:
a gas inlet;
gas openings arranged circumferentially, e.g. at fixed intervals, in or near the inner rim, e.g. open in a radial direction towards a central axis, for circular or hexagonal geometries, or a center plane, for rectangular geometries of the PVD source;
at least one circumferential gas channel connected to the gas inlet and/or the gas openings;
a vacuum tight cooling duct.

The cooling duct can be designed to transport any cooling fluid, essentially circumferentially within the gasring, e.g. between a fluid inlet and outlet port, so that at least the parts of the gas ring round the hot anode and/or cathode can be sufficiently cooled. In most cases the gas ring will be designed to receive cooling water with an internal pressure from 0.1 to 10 bar.

It has been found that a combination of two gas channels can give an essential better gas distribution than a one channel design. Such a construction may comprise a first circumferential gas channel and a second circumferential gas channel, wherein the first gas channel is connected to the gas inlet and the second gas channel is connected to the gas openings in a gas flow direction. Both gas channels are separated by a circumferential flow modifier having an essentially and evenly higher flow resistance along its circumference than each gas channel alone. Therefore, the flow modifier may be designed as a partition wall having small holes evenly arranged on the circumference of the partition wall. As an example the partition wall may have a thickness of 0.5 to 2.5 mm, e.g. from 1 to 2 mm and holes having a diameter D_{H}≤2 mm or 1.0 mm, e.g. 0.5±0.2 mm at fixed intervals from 10 to 150 mm, e.g. from 20 to 100 mm. Alternatively the flow modifier can be a grid or a frit, e.g. a single- or multilayer metal grid or a metal frit having a similar flow resistance like a perforated partition wall as mentioned above.

The gas ring can be made of at least one solid ring or of at least two or more subrings which are joined together. Using as partitioned subrings manufacturing of fluid channels and ducts and their closure(s), e.g. for process gas or cooling water, can be facilitated. Such subrings may comprise a first ring comprising a gas inlet, at least a first part of the gas inlet channel, fluid ports, comprising inlet and outlet ports, e.g. fluid fittings, and at least a first part of inlet and outlet ducts, and a second ring comprising the circumferential gas channel(s) and at least a part of the circumferential cooling duct. The first ring being an outer ring encompassing and/or protruding the outer diameter of the second ring. The second ring being an inner ring in closer proximity to the cathode or target.

The material of the solid ring, of the subrings, or of the first and second ring can be made of a first material having a first coefficient of thermal expansion (CTE). As an example, the material can be stainless steel for standard applications, titanium for applications where a big difference of thermal expansion between ring and anode is needed, or copper if the cooling power should be optimized. Massive subrings of stainless steel can be joined by WIG-welding, whereas for joining the respective thinner components like flow-modifier(s) and covers, e.g. closures or closings to close cavities of the gas ring, laser welding may be used.

The gas ring may further comprise a circumferential anode facing the circumference of the target and being releasably mounted on or near the inner rim. The anode can be made of a second material having a higher coefficient of thermal expansion than the first material and can be made as an anode ring from one piece of material. The second material can be aluminum, or, as far as the first material is from stainless steel or titanium, from copper. When the first material is stainless steel, aluminum is a good choice for the second material in terms of cost efficiency and difference in CTE. Due to the higher CTE of the anode material and the heat load during PVD-processes like sputtering, thereby especially RF-sputtering, or arc evaporation from the target surface, the anode can be pressed outwards into an anode seat formed by a ring wall in parallel to an outer surface of the anode. Therefore, gap size between anode seat an anode should be small enough to ensure good thermal conductance under process conditions but high enough to allow manually (de)mounting of the anode for service purposes. The anode seat, which can be cylindrical as an example for circular PVD sources, should be in parallel to axis Z to absorb expansion forces of the heated anode.

The anode may extend the solid ring or the respective subring carrying the anode in an inward direction towards axis Z which can also symbolize a central plane of a rectangular PVD-source, e.g. from 5 to 30 mm. The inner circumference of the anode hereby is in a line of sight to the target surface, between the target and the other parts of the gas ring, thereby shielding those parts from direct heat radiation or sputtered or evaporated material from the target surface and may at least in part protrude over the target surface or targets fixtures in an inward direction, e.g. by 5 to 20 mm, wherein respective dark space distances and/or isolation has to be obeyed between parts on cathodic and anodic potential.

The anode can be mounted on a first flange being offset outwardly from the inner rim. The flange can be designed to be oriented in an axial direction towards the PVD-source when mounted in the PVD-chamber, e.g. in parallel to the target surface. Screws or other pressing means can be used to press the anode on the first flange to give a good thermal coupling between the cooled ring and the anode.

The gas ring may further comprise a second flange on a step in the inner wall of the ring. The second flange can be provided in an outward direction from the first flange, e.g. to mount the gas ring to the PVD source or a mounting rail of the vacuum chamber.

A third flange can be provided on a step in the outer wall of the ring to mount the gas ring on or to the PVD chamber. Usually second and third flanges will be equipped with gaskets, at least when they have to separate vacuum from atmosphere. At least the second inner flange may also be provided with an RF-shielding, e.g. in form of a copper ring, mesh or the like.

The invention is also directed to a PVD-source comprising a planar target which can be circular or multiangled, e.g. rectangular or hexagonal, and a gas ring as described above. Such PVD sources, where PVD stands for physical vapor deposition, comprise sources designed to evaporate a target material by sputtering or cathodic arc evaporation. In a preferred embodiment the PVD-source is a sputter-source.

The invention is further directed to a vacuum chamber comprising a gas ring according to the present invention or a PVD-source as mentioned above.

It should be emphasized that two or more embodiments of a gas ring, a PVD-source or a vacuum chamber according to the present invention may be combined unless being in contradiction.

### FIGURES

The invention shall now be further exemplified with the help of figures. The figures show:

FIG. 1: A schematic drawing of state-of-the-art gas rings;

FIG. 2: A schematic drawing of an inventive gas ring.

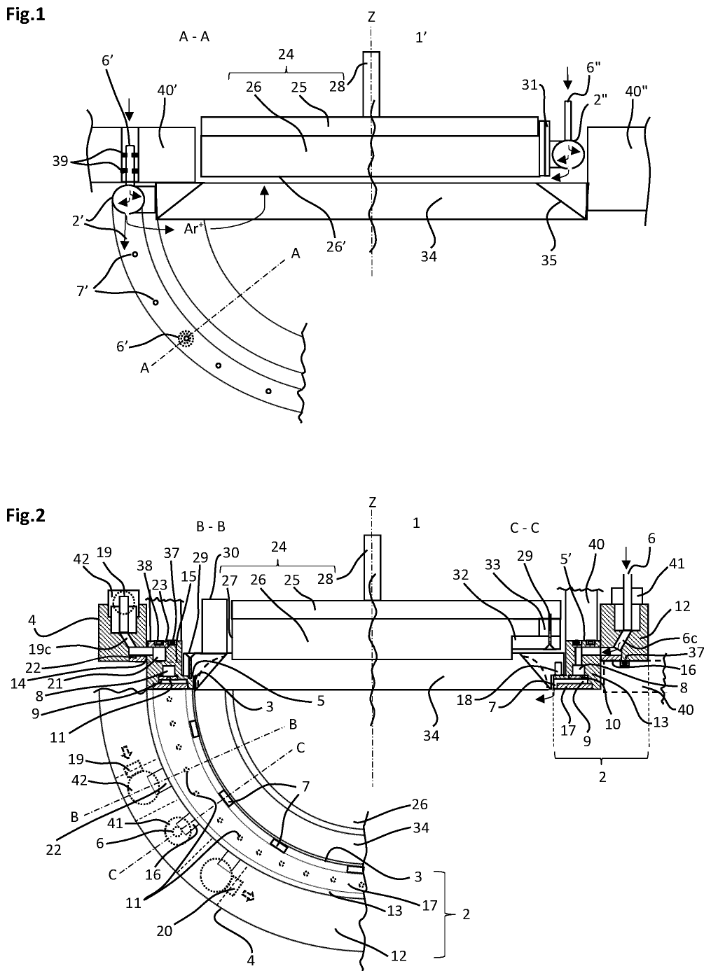

On the left side of FIG. 1, that is left from axis Z, a gas ring 2′ according to the state-of-the-art is shown, mounted in a vacuum chamber 40′ and surrounding an anode 34 of a circular PVD-source 1′, the latter further comprising a cathode 24 having a cathode base 25 with a power connection 28 and a target 26 to be sputtered or evaporated. In the lower left side of FIG. 1 a quadrant of the front face of the PVD-source 1′ is shown, that is towards the surface 26 of the target 26 and the inner surface 35 of the anode which is inclined or concave towards the target surface 26. Openings 7′ in the front side of the gas ring 2′ are directed axially. Cross section A-A is shown in the upper left half of FIG. 1. Gas is fed to gas inlet 6′, distributed within the gas ring 2′ and expelled into the process atmosphere as symbolized by arrows. In the process atmosphere molecules of the process gas can be positively ionized, e.g. Ar to Art, and in the following be attracted towards the target surface 26 for sputtering and/or surface alloying in case of reactive processes where mixtures of inert sputter-gas(s) and reactive gas(s) are used. Gas ring 2″ can be plugged to the vacuum chamber 40′ by a cylindrical gas inlet 6′ comprising two O-rings for press-fitting and sealing. Additional screw or clamp fixings (not shown) will be applied as usually with state-of-the-art gas rings. The anode thereby is mounted directly to a wall of the vacuum chamber 40′ round an aperture for the sputter-source 1′.

On the right side of FIG. 1 another state-of-the-art gas ring 2″ is shown, encompassing the target and situated behind the anode 34 when looking towards the face or front side of the PVD-source 1. Having a cylindrical gas inlet 6″ and gas openings 7″, the ring 2″ is similar in construction to the ring 2′ as shown on the left side. An isolating ring 31 is mounted between the target 26′ and the gas ring 2″ to avoid the generation of parasitic plasmas between the target and the gas ring. In this situation the anode 34′ is mounted within the aperture of the vacuum chamber 40″ which is foreseen for the sputter source 1′. Despite of the widespread use of state-of-the-art gas rings 2′, 2″ as shown with vacuum equipment and PVD-sources 1′ in a wide spread field of surface engineering applications, such gas rings, especially when applied with RF-sputtering still tend to make problems with reference to process stability and uniformity of gas distribution as mentioned in the section technical background.

An inventive gas ring 2 as mounted to a PVD-source 1 in a vacuum chamber 40, symbolized by parts of its vacuum enclosure, is shown in FIG. 2. As with FIG. 1 in the lower left part a quadrant of the front face of the respective PVD-source is shown. In this case with two cross sections as displayed schematically on the left and right upper part of the drawing: At the left side cross section B-B intersecting the gas ring 2 in the area of the cooling fluid inlet duct 19c, and at the right side cross section C-C intersecting at the gas inlet 6. Gas inlet 6 may have a connector 41 as shown with the quadrant scheme below. Fittings 41 and 42 for gas respectively fluid connection can be industrial standard fittings like Swagelok-fittings or the like.

With reference to FIG. 2 a gas ring 2 is shown in a set up comprising an outer subring 12 and inner subring 13 (see cross section C-C) which are welded together, e.g. by a WIG-welding process. An alternative dividing line 15 of the two subrings is shown in dashed lines with cross section B-B. Such alternative subrings can be used to produce a gas ring of the same dimensions and properties. Same reference numbers with FIG. 1 refer to same parts in FIG. 2, also if respective parts of same number may vary in certain aspects of geometry and design. The area comprising the gas inlet 6 or the gas inlet and the fluid inlet 19 may be manufactured as ring inserts and be inserted as e.g. one prefabricated part of the gas ring to ease manufacturing of respective gas inlet channels 6c or fluid inlet ducts 19c, see dashed lines in the lower left quadrant.

The stainless gas ring 2 is delimited in a sidewise direction by an outer rim 4 and by an inner rim 3 towards the anode 34 made of aluminum, or copper in an alternative embodiment. For optimum contact and process-stability the anode is fixed (e.g. with screws 29 or clamps) to the gas ring. Radially elongated slots may be used in the anode 34 to allow respective movement of the aluminum anode towards the cylindrical seat of the stainless gas ring due to the different CTE of the materials. Due to this construction the gas ring 2 and the anode 34 can be pre-assembled and easily mounted together to the PVD-source or the vacuum chamber.

In cross-section B-B details of the cooling fluid supply, which usually will be used with tempered water, can be seen. The fluid system comprising a cooling fluid inlet port 19, a cooling fluid inlet duct 19c, a circumferential cooling duct 21 running from the inlet duct 19c round the gas ring 2 to the outlet duct and thereby to the cooling fluid outlet port 20, which can have the same design feature as the fluid inlet part, both being provided with an outer closing 22 and respective fluid fittings 42. The inner closing ring 23 covers the duct 21, both the outer closing 22 and the inner closing ring 23 can be made from laser welded stainless steel sheets of 0.5 to 2.5 mm thickness to withstand the fluid pressure in the duct, e.g. water at 0.1 to 10 bar. Below the circumferential fluid duct 21, the circumferential gas channels 8 and 9 separated by a flow modifier 10 can be seen. The flow modifier 10 and an inner closure ring 17 which separates the second channel 9 against the vacuum chamber can be again made of laser welded stainless sheets of the same dimensions as mentioned above. For fluid communication between the first 8 and second gas channel 9 holes 11 of 0.5 mm diameter are arranged regularly along the circumference of the flow modifier 10. For fluid communication between the second gas channel 9 and the vacuum chamber 40 (see also respective arrow) gas openings 7 are provided within the inner rim 3. The opening 7 extend to the lower side of the gas ring 2, which refers to the face side of the PVD-source, see also cross section C-C quadrant of source face. By the two channel construction and respective design of the rectangular openings 7 arranged tangential to the inner rim 3 and anode 34, an optimal even distribution of any gas or gas mixture can be provided to the target surface and/or a substrate in front of and centered to the target.

With reference to cross section C-C further details of the gas system are shown with gas flow symbolized by arrows: gas inlet 6, and gas inlet channel 6c, as well as gas channels 8, 9, flow modifier 10, and gas opening 7. On a first flange 5 a centering pin 18 to ease the mounting of the anode 34 can be seen. On a second flange 5′ a gasket 37 and a copper ring 38 are provided as vacuum sealing, e.g. to a cover lid of the vacuum chamber 40, respectively as RF-protection. The ring may further sit with a third flange including an outer closure 16 of the gas inlet channel 6c on a flange of the vacuum chamber 40 (dashed lines) which may comprise a further gasket 37. The anode 35 again can have an inner surface 35 which is inclined (solid) or concave (dashed) towards the target surface 26.

In cross-section B-B the cathode 24 set-up can be the same as with the state-of-the-art set-up in FIG. 1 and may refer to a target 26 which is bonded to the cathode base 25 forming an outer cathode margin 27. Here to an isolating cylinder 30 may surround the cathodically biased parts 25 and 26 in a dark room distance. However, the cathode set-up 24 in cross-section C-C shows a target 26 which is mechanically clamped to the cathode base 25 by clamp ring 32 and distance ring 33 which are screwed to the cathode base 25. Such cathode set-ups can be used with target materials of high mechanical strength and provides a better stability for high power sputtering.

Finally, it should be mentioned that all features as shown or discussed in connection with only one of the embodiments or examples of the present invention and not further discussed with other embodiments can be seen to be features well adapted to improve the performance of other embodiments of the present invention too, as long such a combination cannot be immediately recognized as being prima facie inexpedient for the man of art. Therefore, with the exception as mentioned all combinations of features of certain embodiments can be combined with other embodiments where such features are not mentioned explicitly.

### REFERENCE NUMBERS

1 PVD-source
2,2′,2″ gas ring
3 inner rim
4 outer rim
5,5′ flange
6,6′,6″ gas inlet
6c gas inlet channel
7,7′ gas openings
8 first circumferential gas channel
9 second circumferential gas channel
10 flow modifier
11 holes
12 outer subring
13 inner subring
14 dividing line
15 alternative dividing line
16 outer closure
17 inner closure ring
18 centering pin
19 cooling fluid inlet port
19c cooling fluid inlet/outlet duct
20 cooling fluid outlet port
21 circumferential cooling duct
22 outer closing
23 inner closing ring
24 cathode
25 cathode base
26/26′ target/target surface
27 outer margin
28 power connection
29 pressing means (e.g. screw)
30 isolator
31 isolator
32 clamp ring
33 distance ring
34 anode
35 inner anode surface
37 gasket
38 RF-protection
39 seal (O-ring)
40,40′,40″ vacuum chamber
41 gas connector
42 water fitting

What is claimed is:

1-18. (canceled)

19. A PVD-source (1) with a cathode (24) having a target (6) for material deposition, and a gas ring, wherein said gas ring (2) comprises an inner rim (3) and an outer rim (4) and at least one flange (5, 5′) between the inner and the outer rim, said gas ring (2) further comprising:
a gas inlet (6);
gas openings (7) arranged circumferentially in or near the inner rim (3);
at least one circumferential gas channel (8, 9) connected to the gas inlet and/or the gas openings;
a cooling duct (11); and
a circumferential anode facing the circumference of the target and being releasably mounted on or near the inner rim;
wherein the material of the gas ring, of optional subrings, or of an optional first and second ring is of a first material having a first coefficient of thermal expansion (CTE) and the anode is made of a second material having a higher coefficient of thermal expansion than the first material.

20. The PVD-source according to claim 19, wherein the cooling duct is a water duct (10).

21. The PVD-source according to claim 19, comprising a first circumferential gas channel (8) and a second circumferential gas channel (9), the first gas channel (8) being connected to the gas inlet (6), the second gas channel (9) being connected to the gas openings, both gas channels (8,9) being separated by a circumferential flow modifier (10).

22. The PVD-source according to claim 21, wherein the flow modifier is a partition wall having small holes evenly arranged on the circumference of the partition wall.

23. The PVD-source according to claim 21, wherein the flow modifier is a grid or a frit.

24. The PVD-source according to claim 19, said gas ring being made of at least one solid ring or of at least two or more subrings which are joined together.

25. The PVD-source according to claim 23, wherein the subrings comprise a first ring comprising a gas inlet, e.g. a gas connector, at least a first part of a gas inlet channel, fluid ports, and at least a first part of the fluid inlet and outlet ducts, and a second ring comprising the circumferential gas channel(s) and at least a part of the circumferential cooling duct.

26. The PVD-source according to claim 19, wherein the second material is one of aluminum or copper.

27. The PVD-source according to claim 19, wherein the first material is stainless steel and the second material is aluminum.

28. The PVD-source according to claim 19, wherein the anode is mounted on a first flange, said first flange being offset outwardly from the inner rim.

29. The PVD-source according to claim 19, further comprising a second flange on a step in the inner wall of the ring.

30. The PVD-source according to claim 19, further comprising a third flange on a step in the outer wall of the ring.

31. The PVD-source according to claim 19, wherein said PVD-source is a sputter-source.

32. Vacuum chamber comprising a PVD-source with a gas ring according to claim 19.
